(19) United States
(12) Patent Application Publication
(10) Pub. No.: US 2024/0134273 A1
(43) Pub. Date: Apr. 25, 2024

(54) SEMICONDUCTOR PHOTORESIST COMPOSITION AND METHOD OF FORMING PATTERNS USING THE COMPOSITION

(71) Applicant: SAMSUNG SDI CO., LTD., Yongin-si (KR)

(72) Inventors: Kyungsoo MOON, Suwon-si (KR); Young Keun KIM, Suwon-si (KR); Dong Wan RYU, Suwon-si (KR)

(21) Appl. No.: 18/456,127

(22) Filed: Aug. 25, 2023

(30) Foreign Application Priority Data
Oct. 5, 2022 (KR) 10-2022-0127368

(51) Int. Cl. G03F 7/004; C07F 7/22; H01L 21/027

(52) U.S. Cl. CPC G03F 7/0042; C07F 7/2224; C07F 7/226; C07F 7/2284; H01L 21/0271

(57) ABSTRACT

Provided are a semiconductor photoresist composition including an organotin compound represented by Chemical Formula 1 and a solvent, and a method of forming patterns using the same. The method of forming patterns may include forming an etching-objective layer on a substrate, coating the semiconductor photoresist composition on the etching-objective layer to form a photoresist layer, patterning the photoresist layer to form a photoresist pattern, and etching the etching-objective layer using the photoresist pattern as an etching mask.

### CROSS-REFERENCE TO RELATED APPLICATION

This application claims priority to and the benefit of Korean Patent Application No. 10-2022-0127368 filed in the Korean Intellectual Property Office on Oct. 5, 2022, the entire contents of which are hereby incorporated by reference.

### BACKGROUND

### 1. Field

Embodiments of this disclosure relate to a semiconductor photoresist composition and a method of forming patterns using the composition.

### 2. Description of the Related Art

EUV (extreme ultraviolet) lithography is paid attention to as one important technology for manufacturing a next generation semiconductor device. EUV lithography is a pattern-forming technology using an EUV ray having a wavelength of about 13.5 nm as an exposure light source. According to EUV lithography, it is understood that an extremely fine pattern (e.g., less than or equal to about 20 nm) may be formed in an exposure process during a manufacture of a semiconductor device.

The extreme ultraviolet (EUV) lithography is realized through development of compatible photoresists which can be performed at a spatial resolution of less than or equal to about 16 nm. Currently, efforts to satisfy insufficient specifications of existing chemically amplified (CA) photoresists such as a resolution, a photospeed, and feature roughness (or also referred to as a line edge roughness or LER) for the next generation device are being made.

An intrinsic image blurring due to an acid catalyzed reaction in these polymer-type photoresists limits a resolution in small feature sizes, which has been present in electron beam (e-beam) lithography for a long time. Chemically amplified (CA) photoresists are designed for high sensitivity, but because their existing elemental makeups reduce light absorbance of the photoresists at a wavelength of 13.5 nm, and thus, decrease their sensitivity, the chemically amplified (CA) photoresists may partially have more difficulties under an EUV exposure.

In addition, the CA photoresists may have difficulties in the small feature sizes due to roughness issues, and line edge roughness (LER) of the CA photoresists experimentally turns out to be increased, as a photospeed is decreased partially due to an essence of acid catalyst processes. Accordingly, a novel high-performance photoresist is required in a semiconductor industry because of these defects and drawbacks of the CA photoresists.

In order to overcome the aforementioned drawbacks of the chemically amplified (CA) organic photosensitive composition, an inorganic photosensitive composition has been researched. The inorganic photosensitive composition is mainly used for negative tone patterning having resistance against removal by a developer composition due to chemical modification through a nonchemical amplification mechanism. The inorganic composition contains an inorganic element having a higher EUV absorption rate than hydrocarbon, and thus, may secure sensitivity through the nonchemical amplification mechanism and in addition, is less sensitive with respect to a stochastic effect, and thus, has a low line edge roughness and a small number of defects.

Inorganic photoresists based on peroxopolyacids of tungsten mixed together with tungsten, niobium, titanium, and/or tantalum have been reported as radiation sensitive materials for patterning. These materials are effective for patterning large pitches for a bilayer

configuration as far ultraviolet (deep UV), X-ray, and electron beam sources. More recently, when cationic hafnium metal oxide sulfate (HfSOx) materials along with a peroxo complexing agent has been used to image a 15 nm half-pitch (HP) through projection EUV exposure, impressive performance has been obtained. Such systems exhibit the highest performance of a non-CA photoresist and has a practicable photospeed near to a requirement for an EUV photoresist. However, the hafnium metal oxide sulfate material having the peroxo complexing agent has a few practical drawbacks. First, these materials are coated in a mixture of corrosive sulfuric acid/hydrogen peroxide and have insufficient or unsuitable shelf-life stability. Second, a structural change thereof for performance improvement as a composite mixture is not easy. Third, development should be performed in a TMAH (tetramethylammonium hydroxide) solution at an extremely high concentration of 25 wt % and the like.

Recently, active research has been conducted for molecules containing tin that have excellent absorption of extreme ultraviolet rays. As for an organotin polymer among them, alkyl ligands are dissociated by light absorption or secondary electrons produced thereby, and are cross-linked with adjacent chains through oxo bonds, and thus, enable the negative tone patterning which may not be removed by an organic developing solution. This organotin polymer exhibits greatly improved sensitivity as well as maintains a resolution and line edge roughness, but the patterning characteristics need to be additionally improved for commercial availability.

### SUMMARY

Embodiments of the present disclosure provide a semiconductor photoresist composition having improved storage stability and coating property.

Another embodiment provides a method of forming a pattern using the semiconductor photoresist composition.

A semiconductor photoresist composition according to some embodiments includes an organotin compound represented by Chemical Formula 1 and a solvent.

ₘ(R¹)—Sn—(—S—L¹—X)ₙ Chemical Formula 1

In Chemical Formula 1,
L¹ is a single bond, or a substituted or unsubstituted C1 to C5 alkylene group,
R¹ is a substituted or unsubstituted C1 to C20 alkyl group, a substituted or unsubstituted C3 to C20 cycloalkyl group, a substituted or unsubstituted C2 to C20 alkenyl group, a substituted or unsubstituted C3 to C20 cycloalkenyl group, a substituted or unsubstituted C2 to C20 alkynyl group, a substituted or unsubstituted C3 to C20 cycloalkynyl group, a substituted or unsubstituted C6 to C30 aryl group, or a combination thereof,
m and n are each an integer, and 2≤m+n≤6,
X is OR², SR³, C(O)—L²—OR⁴, or C(O)—L³—SR⁵,
L² and L³ are each independently be a single bond, or a substituted or unsubstituted C1 to C5 alkylene group,
R² and R³ are each independently be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and
R⁴ and R⁵ are each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof.
R² to R⁵ may each independently be a substituted or unsubstituted C1 to C20 alkyl group, a substituted or unsubstituted C2 to C20 alkenyl group, a substituted or unsubstituted C2 to C20 alkynyl group, a substituted or unsubstituted C6 to C30 aryl group, or a combination thereof.
R² to R⁵ may each independently be a methyl group, an ethyl group, an n-propyl group, an n-butyl group, an n-pentyl group, an n-hexyl group, an n-heptyl group, an n-octyl group, an n-nonyl group, an n-decyl group, an iso-propyl group, an iso-butyl group, an iso-pentyl group, an iso-hexyl group, an iso-heptyl group, an iso-octyl group, an iso-nonyl group, an iso-decyl group, a sec-butyl group, a sec-pentyl group, a sec-hexyl group, a sec-heptyl group, a sec-octyl group, a tert-butyl group, a tert-pentyl group, a tert-hexyl group, a tert-heptyl group, a tert-octyl group, a tert-nonyl group, or a tert-decyl group.

R¹ may be a substituted or unsubstituted C3 to C20 branched alkyl group.

R¹ may be an iso-propyl group, an iso-butyl group, an iso-pentyl group, an iso-hexyl group, an iso-heptyl group, an iso-octyl group, an iso-nonyl group, an iso-decyl group, a sec-butyl group, a sec-pentyl group, a sec-hexyl group, a sec-heptyl group, a sec-octyl group, a tert-butyl group, a tert-pentyl group, a tert-hexyl group, a tert-heptyl group, a tert-octyl group, a tert-nonyl group, or a tert-decyl group.

L¹ may be a single bond, or a substituted or unsubstituted C1 to C3 alkylene group.

In some embodiments, 4≤m+n≤6.

In some embodiments, m+n=4, m may be an integer of 0 to 2, and n may be an integer of 2 to 4.

The organotin compound may be one selected from the compounds of Group 1.

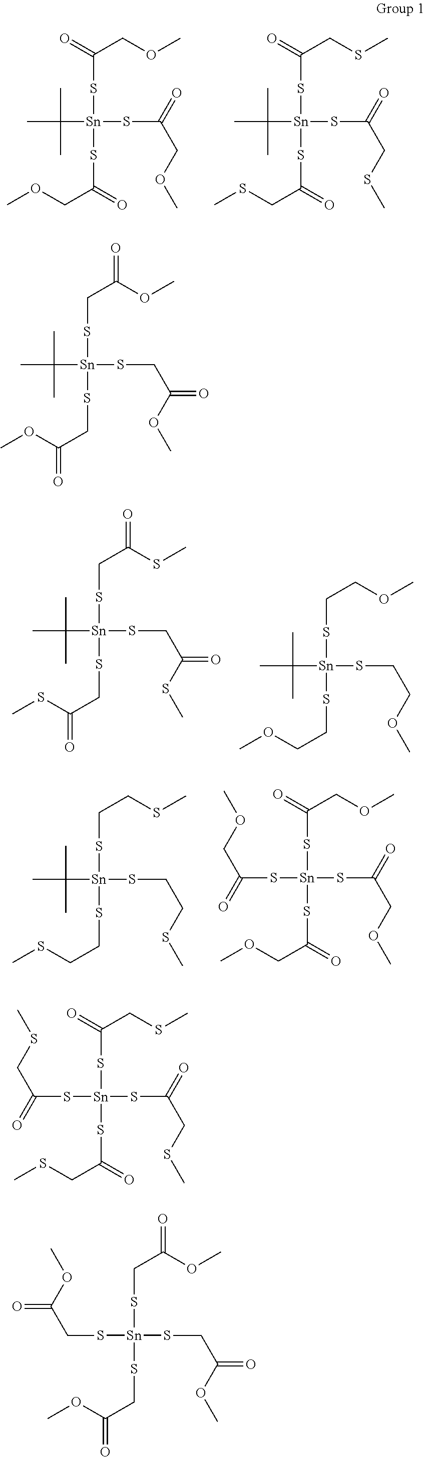

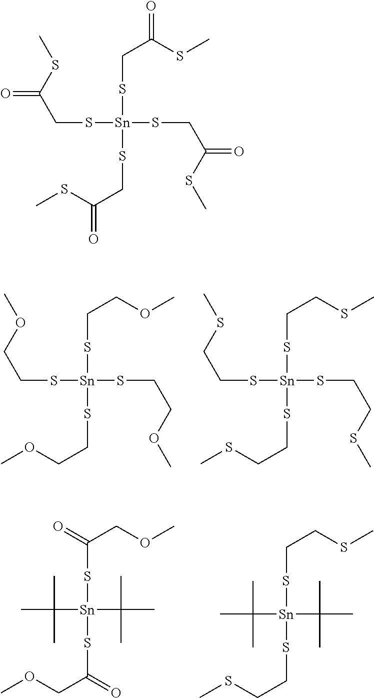

The organotin compound may be included in an amount of about 1 wt % to about 30 wt % based on 100 wt % of the semiconductor photoresist composition.

The semiconductor photoresist composition may further include an additive of a surfactant, a crosslinking agent, a leveling agent, or a combination thereof.

A method of forming patterns according to some embodiments includes forming an etching-objective layer on a substrate, coating the semiconductor photoresist composition on the etching-objective layer to form a photoresist layer, patterning the photoresist layer to form a photoresist pattern, and etching the etching-objective layer using the photoresist pattern as an etching mask.

The photoresist pattern may be formed using light having a wavelength of about 5 nm to about 150 nm.

The method of forming patterns may further include providing a resist underlayer formed between the substrate and the photoresist layer.

The photoresist pattern may have a width of about 5 nm to about 100 nm.

The semiconductor photoresist composition according to some embodiments may provide a photoresist pattern with improved sensitivity while maintaining line edge roughness.

### BRIEF DESCRIPTION OF THE DRAWINGS

The accompanying drawings, together with the specification, illustrate embodiments of the subject matter of the present disclosure, and, together with the description, serve to explain principles of embodiments of the subject matter of the present disclosure.

FIGS. 1 to 5 are cross-sectional views for explaining a method of forming patterns using a semiconductor photoresist composition according to embodiments.

### DETAILED DESCRIPTION

Hereinafter, referring to the drawings, embodiments of the present disclosure are described in more detail. In the following description of embodiments of the present disclosure, well-known functions or constructions may not be described for purposes of clarity.

In order to clearly illustrate embodiments of the present disclosure, the description and relationships are omitted, and throughout the disclosure, the same or similar configuration elements are designated by the same reference numerals. Also, because the size and thickness of each configuration shown in the drawings may be arbitrarily shown for better understanding and ease of description, the present disclosure is not necessarily limited thereto.

In the drawings, the thickness of layers, films, panels, regions, etc., may be exaggerated for clarity. In the drawings, the thickness of a part of layers or regions, etc., may be exaggerated for clarity. It will be understood that when an element such as a layer, film, region, or substrate is referred to as being “on” another element, it can be directly on the other element or intervening elements may also be present.

As used herein, “substituted” refers to replacement of a hydrogen atom by deuterium, a halogen, a hydroxy group, a cyano group, a nitro group, p13 NRR′ (wherein, R and R′ are each independently hydrogen, a substituted or unsubstituted C1 to C30 saturated or unsaturated aliphatic hydrocarbon group, a substituted or unsubstituted C3 to C30 saturated or unsaturated alicyclic hydrocarbon group, or a substituted or unsubstituted C6 to C30 aromatic hydrocarbon group), —SiRR′R″ (wherein, R, R′, and R″ are each independently hydrogen, a substituted or unsubstituted C1 to C30 saturated or unsaturated aliphatic hydrocarbon group, a substituted or unsubstituted C3 to C30 saturated or unsaturated alicyclic hydrocarbon group, or a substituted or unsubstituted C6 to C30 aromatic hydrocarbon group), a C1 to C30 alkyl group, a C1 to C10 haloalkyl group, a C1 to C10 alkylsilyl group, a C3 to C30 cycloalkyl group, a C6 to C30 aryl group, a C1 to C20 alkoxy group, or a combination thereof. “Unsubstituted” refers to non-replacement of a hydrogen atom by another substituent and remaining of the hydrogen atom.

As used herein, when a definition is not otherwise provided, “an alkyl group” refers to a linear or branched aliphatic hydrocarbon group. The alkyl group may be “a saturated alkyl group” without any double bond or triple bond.

The alkyl group may be a C1 to C10 alkyl group. For example, the alkyl group may be a C1 to C8 alkyl group, a C1 to C7 alkyl group, a C1 to C6 alkyl group, or a C1 to C5 alkyl group. For example, the C1 to C5 alkyl group may be a methyl group, an ethyl group, a propyl group, an isopropyl group, an n-butyl group, an isobutyl group, a sec-butyl group, a tert-butyl group, or a 2,2-dimethylpropyl group.

As used herein, when a definition is not otherwise provided, “a cycloalkyl group” refers to a monovalent cyclic aliphatic hydrocarbon group.

The cycloalkyl group may be a C3 to C10 cycloalkyl group, for example, a C3 to C8 cycloalkyl group, a C3 to C7 cycloalkyl group, a C3 to C6 cycloalkyl group, a C3 to C5 cycloalkyl group, or a C3 to C4 cycloalkyl group. For example, the cycloalkyl group may be a cyclopropyl group, a cyclobutyl group, a cyclopentyl group, or a cyclohexyl group, but is not limited thereto.

As used herein, “an aryl group” refers to a substituent in which all atoms in the cyclic substituent have a p-orbital and these p-orbitals are conjugated and may include a monocyclic or fused ring polycyclic functional group (e.g., rings sharing adjacent pairs of carbon atoms) functional group.

As used herein, unless otherwise defined, “an alkenyl group” refers to an aliphatic unsaturated alkenyl group including at least one double bond as a linear or branched aliphatic hydrocarbon group.

As used herein, unless otherwise defined, “an alkynyl group” refers to an aliphatic unsaturated alkynyl group including at least one triple bond as a linear or branched aliphatic hydrocarbon group.

In the chemical formulas described herein, t-Bu refers to a tert-butyl group.

Hereinafter, a semiconductor photoresist composition according to embodiments is described.

A semiconductor photoresist composition according to embodiments of the present disclosure includes an organotin compound represented by Chemical Formula 1 and a solvent.

ₘ(R¹)—Sn—(—S—L¹—X)ₙ Chemical Formula 1
L¹ is a single bond, or a substituted or unsubstituted C1 to C5 alkylene group,
R¹ is a substituted or unsubstituted C1 to C20 alkyl group, a substituted or unsubstituted C3 to C20 cycloalkyl group, a substituted or unsubstituted C2 to C20 alkenyl group, a substituted or unsubstituted C3 to C20 cycloalkenyl group, a substituted or unsubstituted C2 to C20 alkynyl group, a substituted or unsubstituted C3 to C20 cycloalkynyl group, a substituted or unsubstituted C6 to C30 aryl group, or a combination thereof,
m and n are each an integer, and 2≤m+n≤6,
X is OR², SR³, C(O)—L²—OR⁴, or C(O)—L³—SR⁵;
L² and L³ are each independently be a single bond, or a substituted or unsubstituted C1 to C5 alkylene group,
R² and R³ are each independently be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and
R⁴ and R⁵ are each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof.

Because the organotin compound of Chemical Formula 1 provides an additional coordination bond site to a central metal Sn from a functional group including at least one selected from O, S, and C(O) represented by X in addition to S directly bonded to Sn, intramolecular coordination bonds as well as intermolecular bonds are induced due to the unshared electron pairs of O or S, which may be advantageous for forming a matrix.

In some embodiments, compared with tetravalently coordinated common monomolecules, the additional coordination bond meets the coordination number of Sn and structurally covers the Sn atom, which may improve moisture stability and prevent or reduce an aggregation phenomenon caused by a condensation reaction after hydrolysis, thereby increasing long-term storage-stability. Accordingly, because defects are effectively reduced in the coating process, the organotin compound may also affect (e.g., improve) coating stability.

In addition, bonds to a substrate may be strengthened, which may improve a binding force therebetween and resultantly, improve thin film stability.

In addition, because the aggregation phenomenon is prevented or reduced, the coating may be coated in an amorphous form without the use of an additive during spin coating, thereby improving sensitivity and coating properties.

For example, R² to R⁵ may each independently be a substituted or unsubstituted C1 to C20 alkyl group, a substituted or unsubstituted C2 to C20 alkenyl group, a substituted or unsubstituted C2 to C20 alkynyl group, a substituted or unsubstituted C6 to C30 aryl group, or a combination thereof.

As an example, R² to R⁵ may each independently be a methyl group, an ethyl group, an n-propyl group, an n-butyl group, an n-pentyl group, an n-hexyl group, an n-heptyl group, an n-octyl group, an n-nonyl group, an n-decyl group, an iso-propyl group, an iso-butyl group, an iso-pentyl group, an iso-hexyl group, an iso-heptyl group, an iso-octyl group, an iso-nonyl group, an iso-decyl group, a sec-butyl group, a sec-pentyl group, a sec-hexyl group, a sec-heptyl group, a sec-octyl group, a tert-butyl group, a tert-pentyl group, a tert-hexyl group, a tert-heptyl group, a tert-octyl group, a tert-nonyl group, or a tert-decyl group.

For example, R¹ may be a substituted or unsubstituted C3 to C20 branched alkyl group.

The term “branched alkyl group,” as used herein, refers to a form in which a metal-bonded carbon atom is a secondary carbon, a tertiary carbon or a quaternary carbon and may be, for example, an iso-propyl group, an iso-butyl group, an iso-pentyl group, an iso-hexyl group, an iso-heptyl group, an iso-octyl group, an iso-nonyl group, an iso-decyl group, a sec-butyl group, a sec-pentyl group, a sec-hexyl group, a sec-heptyl group, a sec-octyl group, a tert-butyl group, a tert-pentyl group, a tert-hexyl group, a tert-heptyl group, a tert-octyl group, a tert-nonyl group, or a tert-decyl group.

For example, L¹ may be a single bond, or a substituted or unsubstituted C1 to C3 alkylene group.

In some embodiments, L¹ may be a single bond, a substituted or unsubstituted methylene group, a substituted or unsubstituted ethylene group, or a substituted or unsubstituted propylene group.

For example, m and n may be 4≤m+n≤6.

As an example, m+n=4, m may be an integer of 0 to 2, and n may be an integer of 2 to 4.

Examples of the organotin compound include compounds of Group 1.

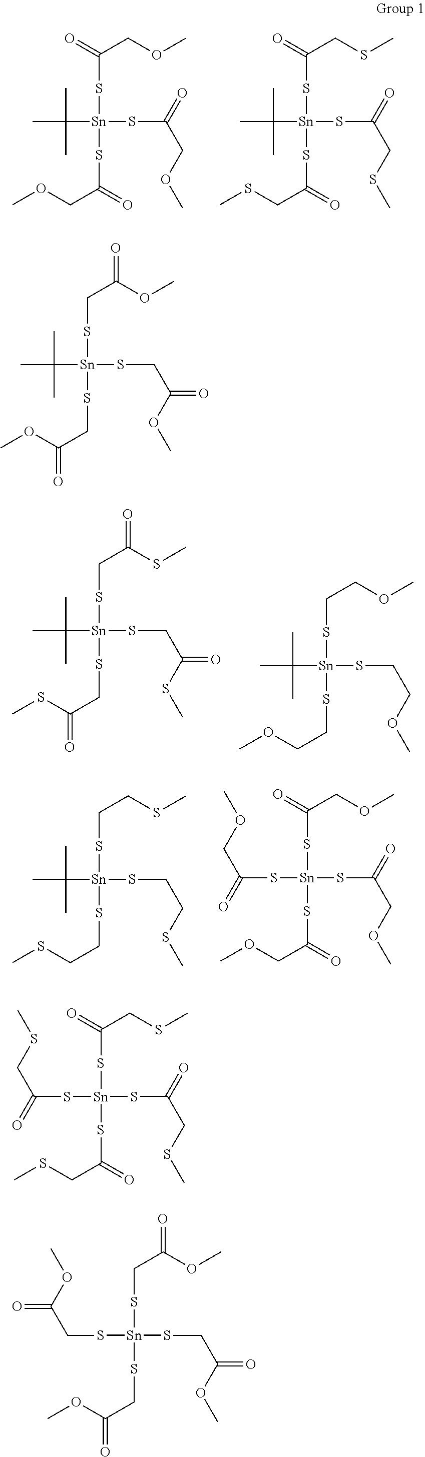

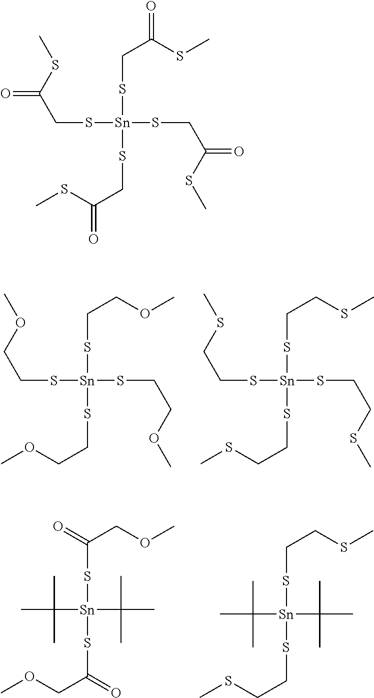

The organotin compound strongly absorbs extreme ultraviolet light at 13.5 nm, and thus, may have excellent sensitivity to light having high energy such as, for example, the light used in EUV lithography.

In the semiconductor photoresist composition according to some

embodiments, the organotin compound may be included in an amount of about 1 wt % to about 30 wt %, for example, about 1 wt % to about 25 wt %, for example, about 1 wt % to about 20 wt %, for example, about 1 wt % to about 15 wt %, for example, about 1 wt % to about 10 wt %, for example, about 1 wt % to about 5 wt % based on 100 wt % of the semiconductor photoresist composition, but the present disclosure is not limited to thereto. When the organotin compound is included in an amount within the above range, storage stability and etch resistance of the semiconductor photoresist composition are improved, and resolution characteristics are improved.

Because the semiconductor photoresist composition according to some embodiments of the present disclosure includes the aforementioned organotin compound, a semiconductor photoresist composition having excellent sensitivity and pattern formation properties may be provided.

The solvent of the semiconductor photoresist composition according to the embodiment may be an organic solvent, and may be, for example, aromatic compounds (e.g., xylene, toluene, etc.), alcohols (e.g., 4-methyl-2-pentenol, 4-methyl-2-propanol, 1-butanol, methanol, isopropyl alcohol, 1-propanol), ethers (e.g., anisole, tetrahydrofuran), esters (n-butyl acetate, propylene glycol monomethyl ether acetate, ethyl acetate, ethyl lactate), ketones (e.g., methyl ethyl ketone, 2-heptanone), or a mixture thereof, but the present disclosure is not limited thereto.

In some embodiments, the semiconductor photoresist composition may further include a resin in addition to the organotin compound and the solvent.

The resin may be a phenolic resin including at least one aromatic moiety of Group 2.

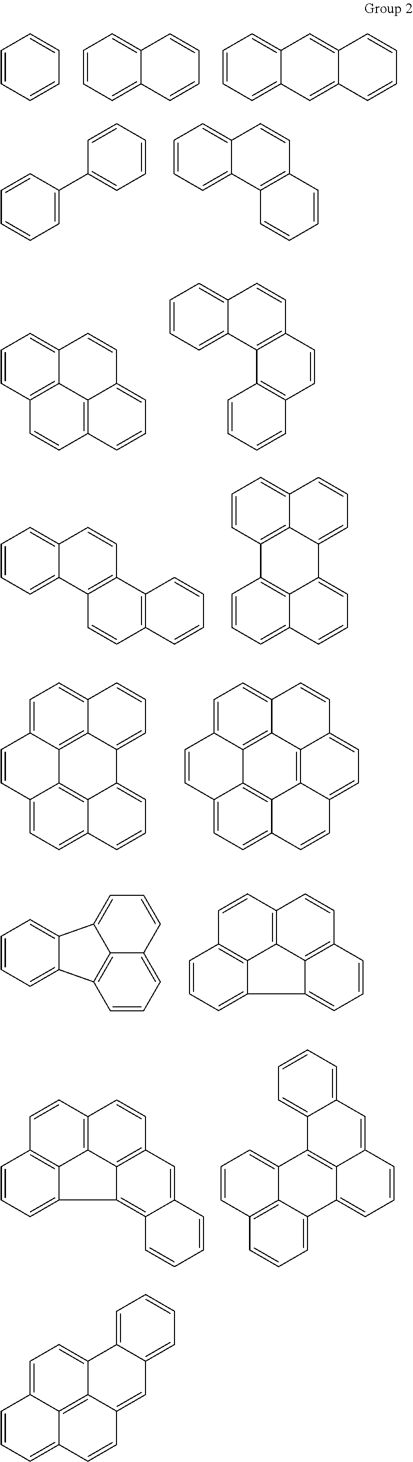

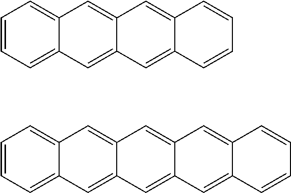

The resin may have a weight average molecular weight of about 500 to about 20,000 (e.g., 500 to 20,000 daltons).

The resin may be included in an amount of about 0.1 wt % to about 50 wt % based on the total amount of the semiconductor photoresist composition.

When the resin is included in the above content range, it may have excellent etch resistance and heat resistance.

On the other hand, the semiconductor photoresist composition according to

embodiments is suitably or desirably made of the aforementioned organotin compound, a solvent, and a resin. However, the semiconductor resist composition according to some embodiments may further include additives as needed or desired. Examples of the additives may include a surfactant, a crosslinking agent, a leveling agent, an organic acid, a quencher, or a combination thereof.

The surfactant may include, for example, an alkyl benzene sulfonate salt, an alkyl pyridinium salt, polyethylene glycol, a quaternary ammonium salt, or a combination thereof, but the present disclosure is not limited thereto.

The crosslinking agent may be, for example, a melamine-based crosslinking agent, a substituted urea-based crosslinking agent, an acryl-based crosslinking agent, an epoxy-based crosslinking agent, and/or a polymer-based crosslinking agent, but the present disclosure is not limited thereto. The crosslinking agent may have at least two crosslinking forming substituents, for example, a compound such as methoxymethylated glycoluril, butoxymethylated glycoluril, methoxymethylated melamine, butoxymethylated melamine, methoxymethylated benzoguanamine, butoxymethylated benzoguanamine, 4-hydroxybutyl acrylate, acrylic acid, urethane acrylate, acryl methacrylate, 1,4-butanediol diglycidyl ether, glycidol, diglycidyl 1,2-cyclohexane dicarboxylate, trimethylpropane triglycidyl ether, 1,3-bis(glycidoxypropyl)tetramethyldisiloxane, methoxymethylated urea, butoxymethylated urea, and/or methoxymethylated thiourea, and/or the like.

The leveling agent may be used for improving coating flatness during printing and may be any suitable leveling agent generally available in the art.

The organic acid may be p-toluene sulfonic acid, benzenesulfonic acid, p-dodecylbenzene sulfonic acid, 1,4-naphthalene disulfonic acid, methane sulfonic acid, a fluorinated sulfonium salt, malonic acid, citric acid, propionic acid, methacrylic acid, oxalic acid, lactic acid, glycolic acid, succinic acid, or a combination thereof, but the present disclosure is not limited thereto.

The quencher may be diphenyl (p-triyl) amine, methyl diphenyl amine, triphenyl amine, phenylenediamine, naphthylamine, diaminonaphthalene, or a combination thereof.

An amount of the additives included in the semiconductor resist composition may be controlled depending on suitable or desired properties.

In addition, the semiconductor resist composition may further include a silane coupling agent as an adherence enhancer in order to improve a close-contacting force with the substrate (e.g., in order to improve adherence of the semiconductor photoresist composition to the substrate). The silane coupling agent may be, for example, a silane compound including a carbon-carbon unsaturated bond such as vinyltrimethoxysilane, vinyltriethoxysilane, vinyl trichlorosilane, vinyltris(β-methoxyethoxy)silane; and/or 3-methacryloxypropyltrimethoxysilane, 3-acryloxypropyltrimethoxysilane, p-styryl trimethoxysilane, 3-methacryloxypropylmethyldimethoxysilane, 3-methacryloxypropylmethyl diethoxysilane; trimethoxy[3-(phenylamino)propyl]silane, and/or the like, but the present disclosure is not limited thereto.

The semiconductor photoresist composition may be formed into a pattern having a high aspect ratio without a collapse (e.g., without or substantially without collapse of the pattern). Accordingly, in order to form a fine pattern having a width of, for example, about 5 nm to about 100 nm, about 5 nm to about 80 nm, about 5 nm to about 70 nm, about 5 nm to about 50 nm, about 5 nm to about 40 nm, about 5 nm to about 30 nm, about 5 nm to about 20 nm, or about 5 nm to about 10 nm, the semiconductor photoresist composition may be used for a photoresist process using light in a wavelength range from about 5 nm to about 150 nm, for example, about 5 nm to about 100 nm, about 5 nm to about 80 nm, about 5 nm to about 50 nm, about 5 nm to about 30 nm, or about 5 nm to about 20 nm. Accordingly, the semiconductor photoresist composition according to embodiments may be used to realize extreme ultraviolet lithography using an EUV light source that emits light having a wavelength of about 13.5 nm.

According to some embodiments, a method of forming patterns using the aforementioned semiconductor photoresist composition is provided. For example, the manufactured pattern may be a photoresist pattern.

The method of forming patterns according to some embodiments includes forming an etching-objective layer on a substrate, coating the semiconductor photoresist composition on the etching-objective layer to form a photoresist layer, patterning the photoresist layer to form a photoresist pattern, and etching the etching-objective layer using the photoresist pattern as an etching mask.

Hereinafter, a method of forming patterns using the semiconductor photoresist composition is described referring to FIGS. 1 to 5. FIGS. 1 to 5 are cross-sectional views for explaining a method of forming patterns using a semiconductor photoresist composition according to some embodiments.

Referring to FIG. 1, an object for etching is prepared. The object for etching may be a thin film 102 formed on a semiconductor substrate 100. Hereinafter, the object for etching is limited to the thin film 102. A whole surface of the thin film 102 is washed to remove impurities and/or the like that were remaining thereon. The thin film 102 may be for example a silicon nitride layer, a polysilicon layer, and/or a silicon oxide layer.

Subsequently, the resist underlayer composition for forming a resist underlayer 104 is spin-coated on the surface of the washed thin film 102. However, embodiments are not limited thereto, and various suitable coating methods generally available in the art may be used. In some embodiments, the coating methods may include a spray coating, a dip coating, a knife edge coating, a printing method, for example an inkjet printing and/or a screen printing, and/or the like.

The coating process of the resist underlayer may be omitted, and hereinafter, a process including a coating of the resist underlayer is described.

The coated composition is dried and baked to form a resist underlayer 104 on the thin film 102. The baking may be performed at 100° C. to 500° C., for example, 100° C. to 300° C.

The resist underlayer 104 is formed between the substrate 100 and a photoresist layer 106, and thus, may prevent or reduce non-uniformity and deteriorated pattern-forming capability of a photoresist line width that would otherwise occur when a ray reflected from an interface between the substrate 100 and the photoresist layer 106 or a hardmask between layers is scattered into an unintended photoresist region.

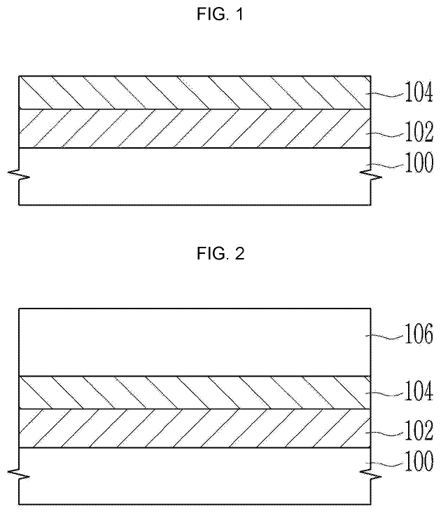

Referring to FIG. 2, the photoresist layer 106 is formed by coating the semiconductor photoresist composition on the resist underlayer 104. The photoresist layer 106 is obtained by coating the aforementioned semiconductor photoresist composition on the thin film 102 formed on the substrate 100 and then, curing it through a heat treatment.

In some embodiments, the formation of a pattern by using the semiconductor photoresist composition may include coating the semiconductor photoresist composition on the substrate 100 having the thin film 102 through spin coating, slit coating, inkjet printing, and/or the like and then, drying it to form the photoresist layer 106.

The semiconductor photoresist composition has already been described in more detail above and will not be described again here.

Subsequently, a substrate 100 having the photoresist layer 106 is subjected to a first baking process. The first baking process may be performed at about 80° C. to about 120° C.

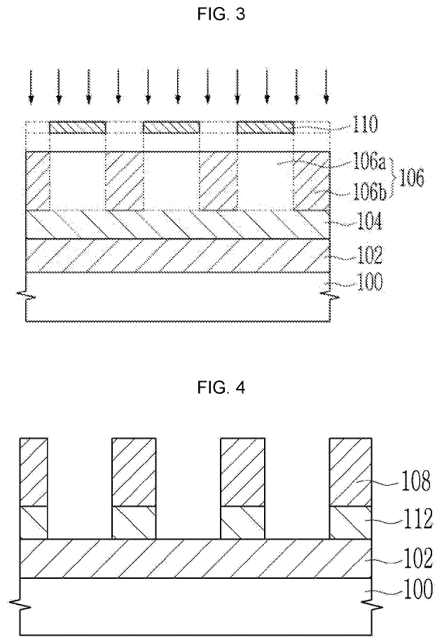

Referring to FIG. 3, the photoresist layer 106 may be selectively exposed.

For example, the exposure may use an activation radiation including light having a short wavelength and a high energy such as EUV (extreme ultraviolet; a wavelength of 13.5 nm), an E-Beam (an electron beam), and/or the like as well as a short wavelength such as an i-line (a wavelength of 365 nm), a KrF excimer laser (a wavelength of 248 nm), an ArF excimer laser (a wavelength of 193 nm), and/or the like.

In some embodiments, light for the exposure may have a short wavelength range from about 5 nm to about 150 nm and a high energy, for example, EUV (extreme ultraviolet; a wavelength of 13.5 nm), an E-Beam (an electron beam), and/or the like.

The exposed region 106b of the photoresist layer 106 has a different solubility from the non-exposed region 106a of the photoresist layer 106 by forming a polymer by way of a crosslinking reaction such as, for example, a condensation reaction between organometallic compounds.

Subsequently, the substrate 100 is subjected to a second baking process. The second baking process may be performed at a temperature of 90° C. to 200° C. The exposed region 106b of the photoresist layer 106 becomes indissoluble by a developing solution due to the second baking process (e.g., the exposed region 106b cannot be dissolved by the developing solution after the second baking process).

In FIG. 4, the non-exposed region 106a of the photoresist layer is dissolved and removed using the developing solution to form a photoresist pattern 108. In some embodiments, the non-exposed region 106a of the photoresist layer is dissolved and removed by using an organic solvent such as 2-heptanone and/or the like to complete the photoresist pattern 108 corresponding to the negative tone image.

As described above, a developing solution used in a method of forming patterns according to some embodiments may be an organic solvent. The organic solvent used in the method of forming patterns according to some embodiments may be, for example, ketones such as methylethylketone, acetone, cyclohexanone, 2-heptanone, and/or the like, alcohols such as 4-methyl-2-propanol, 1-butanol, isopropanol, 1-propanol, methanol, and/or the like, esters such as propylene glycol monomethyl ether acetate, ethyl acetate, ethyl lactate, n-butyl acetate, butyrolactone, and/or the like, aromatic compounds such as benzene, xylene, toluene, and/or the like, or a combination thereof.

However, the photoresist pattern according to some embodiments is not necessarily limited to the negative tone image but may be formed to have a positive tone image. Herein, a developing agent used for forming the positive tone image may be a quaternary ammonium hydroxide composition such as tetraethylammonium hydroxide, tetrapropylammonium hydroxide, tetrabutylammonium hydroxide, or a combination thereof.

As described above, exposure to light having a high energy such as EUV (extreme ultraviolet; a wavelength of 13.5 nm), an E-Beam (an electron beam), and/or the like as well as light having a short wavelength such as i-line (wavelength of 365 nm), KrF excimer laser (wavelength of 248 nm), ArF excimer laser (wavelength of 193 nm), and/or the like may provide a photoresist pattern 108 having a width of a thickness of 5 nm to 100 nm. For example, the photoresist pattern 108 may have a width of a thickness of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, about 5 nm to about 20 nm, or about 5 nm to about 10 nm.

In some embodiments, the photoresist pattern 108 may have a pitch of having a half-pitch of less than or equal to about 50 nm, for example less than or equal to about 40 nm, for example less than or equal to about 30 nm, for example less than or equal to about 20 nm, for example less than or equal to about 10 nm, and a line width roughness of less than or equal to about 5 nm, less than or equal to about 3 nm, less than or equal to about 2 nm, or less than or equal to about 1 nm.

Subsequently, the photoresist pattern 108 is used as an etching mask to etch the resist underlayer 104. Through this etching process, an organic layer pattern 112 is formed. The organic layer pattern 112 also may have a width corresponding to that of the photoresist pattern 108.

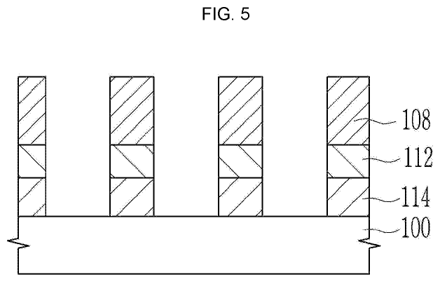

Referring to FIG. 5, the photoresist pattern 108 is used as an etching mask to etch the thin film 102. As a result, the thin film is formed as a thin film pattern 114. The thin film pattern 114 also may have a width corresponding to that of the photoresist pattern 108.

The etching of the thin film 102 may include, for example, dry etching using an etching gas and the etching gas may include, for example, CHF₃, CF₄, Cl₂, BCl₃, and/or a mixed gas thereof.

In the exposure process, the thin film pattern 114 formed by using the photoresist pattern 108 formed through the exposure process performed by using an EUV light source may have a width corresponding to that of the photoresist pattern 108. For example, the thin film pattern 114 may have a width of 5 nm to 100 nm which is equal to (or substantially equal to) that of the photoresist pattern 108. For example, the thin film pattern 114 formed by using the photoresist pattern 108 formed through the exposure process performed by using an EUV light source may have a width of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, or about 5 nm to about 20 nm, or, for example, a width of less than or equal to about 20 nm, like (or substantially like) that of the photoresist pattern 108.

Hereinafter, embodiments of the present disclosure will be described in more detail through examples of the preparation of the aforementioned semiconductor photoresist composition. However, the present disclosure is technically not restricted by the following examples.

### Synthesis of Organotin Compounds

### Synthesis Example 1

10 g of an organotin compound represented by Chemical Formula A was dissolved in 30 ml of toluene, and 8 g of 2-methoxyethanethioic S-acid was slowly added thereto and then, stirred for 6 hours at room temperature (20±5° C.). Subsequently, the toluene and the released propionic acid were removed by vacuum distillation, thereby obtaining a compound represented by Chemical Formula 1a-1.

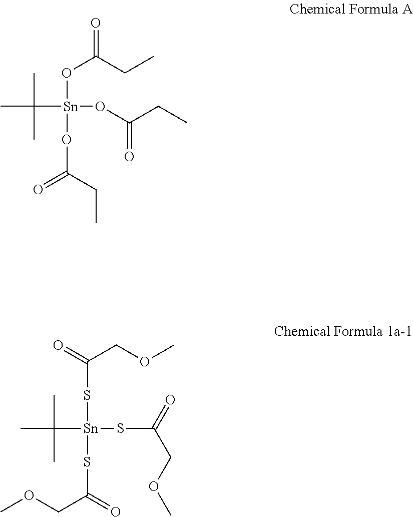

### Synthesis Example 2

A compound represented by Chemical Formula 1a-2 was obtained in substantially the same manner as in Synthesis Example 1 except that 9.2 g of 2-(methylthio)ethanethioic S-acid was used instead of 2-methoxyethanethioic S-acid.

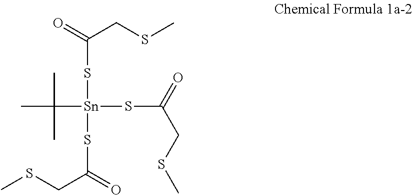

### Synthesis Example 3

A compound represented by Chemical Formula 1 b-1 was obtained in substantially the same manner as in Synthesis Example 1 except that 8 g of methyl 2-mercaptoacetate was used instead of 2-methoxyethanethioic S-acid.

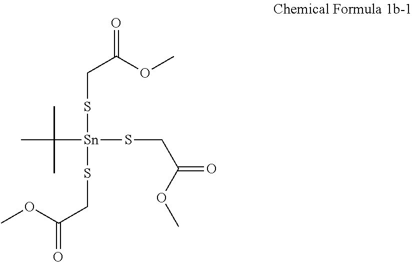 [SMILES: COC(=O)C[S][Sn]([S]CC(=O)OC)([S]CC(=O)OC)[C](C)(C)C]

### Synthesis Example 4

A compound represented by Chemical Formula 1b-2 was obtained in substantially the same manner as in Synthesis Example 1 except that 9.2 g of S-methyl 2-mercaptoethanethioate was used instead of 2-methoxyethanethioic S-acid.

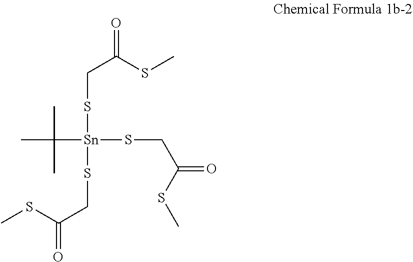 [SMILES: CSC(=O)C[S][Sn]([S]CC(=O)SC)([S]CC(=O)SC)[C](C)(C)C]

### Synthesis Example 5

10 g of an organotin compound represented by Chemical Formula B was dissolved in 30 ml of toluene, and 6.9 g of 2-methoxyethane-1-thiol was slowly added thereto and then, stirred for 6 hours at room temperature. Subsequently, the toluene and the released diethylamine were removed by vacuum distillation, thereby obtaining a compound represented by Chemical Formula 1c-1.

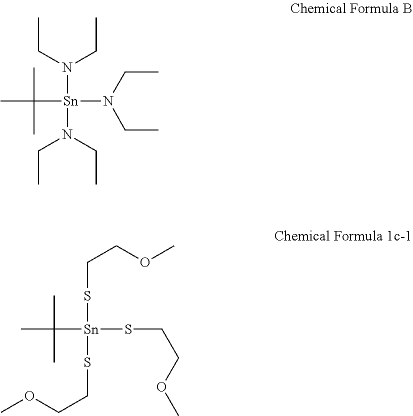

### Synthesis Example 6

A compound represented by Chemical Formula 1 c-2 was obtained in substantially the same manner as in Synthesis Example 5 except that 8.2 g of 2-(methylthio)ethane-1-thiol was used instead of 2-methoxyethane-1-thiol.

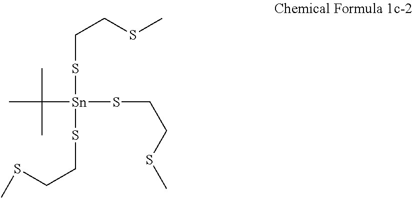

### Synthesis Example 7

10 g of an organotin compound represented by Chemical Formula C was dissolved in 30 ml of toluene, and 10.3 g of 2-methoxyethanethioic S-acid was slowly added thereto and then, stirred for 6 hours at room temperature. Subsequently, the toluene and the released diethylamine were removed by vacuum distillation, thereby obtaining a compound represented by Chemical Formula 1d-1.

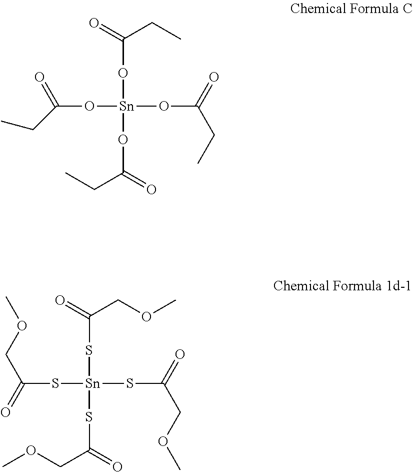 [SMILES: CCC(=O)[O][Sn]([O]C(=O)CC)([O]C(=O)CC)[O]C(=O)CC ; COCC(=O)[S][Sn]([S]C(=O)COC)([S]C(=O)COC)[S]C(=O)COC]

### Synthesis Example 8

A compound represented by Chemical Formula 1d-2 was obtained in substantially the same manner as in Synthesis Example 7 except that 11.9 g of 2-(methylthio)ethanethioic S-acid was used instead of 2-methoxyethane-1-thiol.

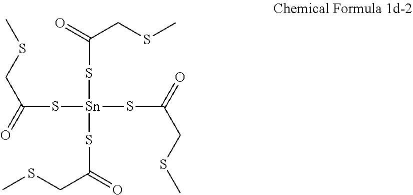 [SMILES: CSCC(=O)[S][Sn]([S]C(=O)CSC)([S]C(=O)CSC)[S]C(=O)CSC]

### Synthesis Example 9

A compound represented by Chemical Formula 1e-1 was obtained in substantially the same manner as in Synthesis Example 7 except that 10.3 g of methyl 2-mercaptoacetate was used instead of 2-methoxyethane-1-thiol.

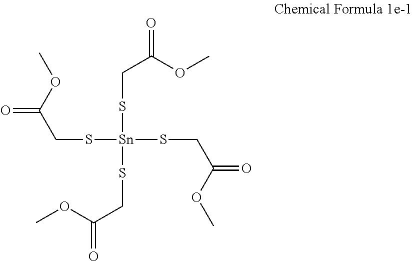 [SMILES: COC(=O)C[S][Sn]([S]CC(=O)OC)([S]CC(=O)OC)[S]CC(=O)OC]

### Synthesis Example 10

A compound represented by Chemical Formula 1e-2 was obtained in substantially the same manner as in Synthesis Example 7 except that 11.9 g of S-methyl 2-mercaptoethanethioate was used instead of 2-methoxyethanethioic S-acid.

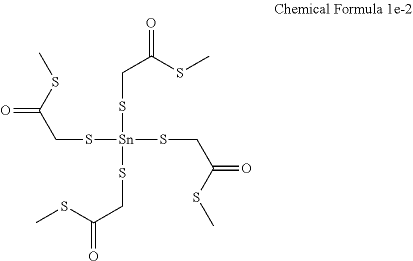 [SMILES: CSC(=O)C[S][Sn]([S]CC(=O)SC)([S]CC(=O)SC)[S]CC(=O)SC]

### Synthesis Example 11

10 g of an organotin compound represented by Chemical Formula D was dissolved in 30 ml of toluene, and 9 g of 2-methoxyethane-1-thiol was slowly added thereto and then, stirred for 6 hours at room temperature. Subsequently, the toluene and the released diethylamine were removed by vacuum distillation, thereby obtaining a compound represented by Chemical Formula 1f-1.

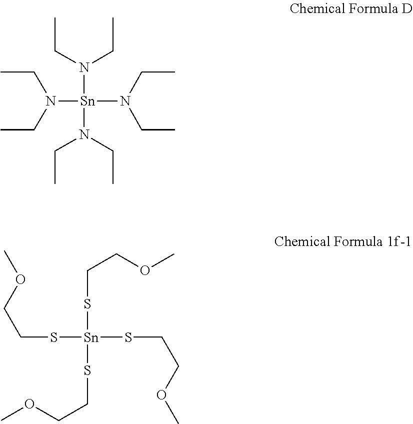

### Synthesis Example 12

A compound represented by Chemical Formula 1f-2 was obtained in substantially the same manner as in Synthesis Example 11 except that 10.6 g of 2-(methylthio)ethane-1-thiol was used instead of 2-methoxyethane-1-thiol.

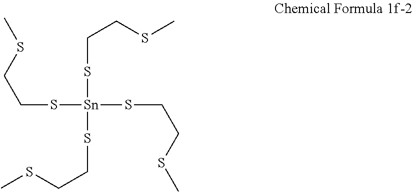

### Synthesis Example 13

10 g of an organotin compound represented by Chemical Formula E was dissolved in 30 ml of toluene, and 5.6 g of 2-methoxyethanethioic S-acid was slowly added thereto and then, stirred for 6 hours at room temperature. Subsequently, the toluene and the released diethylamine were removed by vacuum distillation, thereby obtaining a compound represented by Chemical Formula 1g.

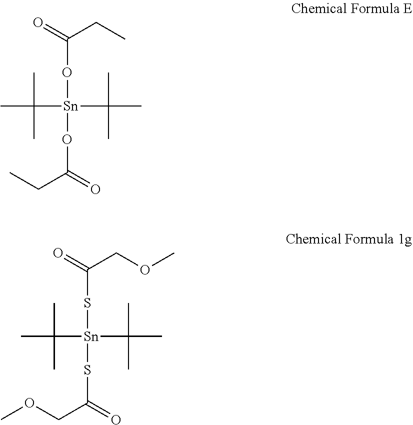

### Synthesis Example 14

10 g of an organotin compound represented by Chemical Formula F was dissolved in 30 ml of toluene, and 5.7 g of 2-(methylthio)ethane-1-thiol was slowly added thereto and then, stirred for 6 hours at room temperature.

Subsequently, the toluene and the released diethylamine were removed by vacuum distillation, thereby obtaining a compound represented by Chemical Formula 1h.

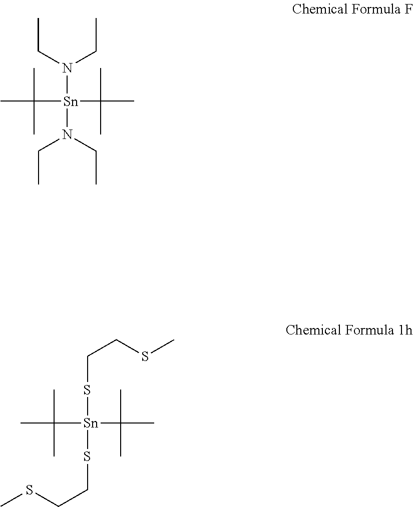

### Comparative Synthesis Example 1

A compound represented by Chemical Formula C1 was obtained in substantially the same manner as in Synthesis Example 1 except that 5.8 g of thioacetic acid was used instead of 2-methoxyethanethioic S-acid.

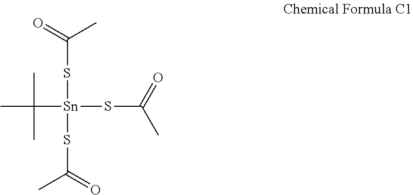 [SMILES: CC(=O)[S][Sn]([S]C(C)=O)([S]C(C)=O)[C](C)(C)C]

### Comparative Synthesis Example 2

A compound represented by Chemical Formula C2 was obtained in substantially the same manner as in Synthesis Example 13 except that 4 g of thioacetic acid was used instead of 2-methoxyethanethioic S-acid.

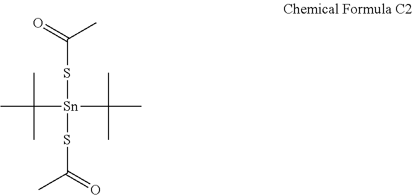 [SMILES: CC(=O)[S][Sn]([S]C(C)=O)([C](C)(C)C)[C](C)(C)C]

### Preparation of Semiconductor Photoresist Composition

### Examples 1 to 14 and Comparative Examples 1 to 2

The compounds represented by Chemical Formulas 1a-1 to 1h according to Synthesis Examples 1 to 14 and the compounds represented by Chemical Formulas C1 and C2 according to Comparative Synthesis Examples 1 to 2 were respectively dissolved in PGMEA (propylene glycol monomethyl ether acetate) at 3 wt % and then, filtered with a 0.1 μm PTFE syringe filter, thereby preparing each photoresist composition.

### Evaluation 1: Storage Stability

For the photoresist compositions used in Examples 1 to 14 and Comparative Examples 1 to 2, storage stability was evaluated based on the following criteria, and the results are shown in Table 1.

The semiconductor photoresist compositions according to Examples 1 to 14, and Comparative Examples 1 to 2 were left for a predetermined period at room temperature (20±5° C.) and then, examined with naked eyes with respect to a degree of precipitation and evaluated into 2 levels according to the following storability criteria.
Evaluation Criteria
◯: can be stored for more than 3 months
X: can be stored for more than or equal to 1 month and less than 3 months

### Evaluation 2: Coating Uniformity

The semiconductor photoresist compositions according to Examples 1 to 14 and Comparative Examples 1 to 2 were spin-coated at 1500 rpm for 30 seconds on a circular silicon wafer having a native-oxide surface and a diameter of 4 inches and then, baked on a hot plate at 160° C. for 120 seconds, thereby forming each thin film. Subsequently, ten points crossing the center of the wafer were randomly selected to obtain Rq by surface analysis through AFM (atomic force microscopy). (When Rq was less than or equal to 0.3, coating uniformity was judged to be excellent.)

TABLE 1

| | Organometallic | Storage | Coating |
|---|---|---|---|
| | compound | stability | uniformity |
| Example 1 | Compound 1a-1 | ◯ | 0.25 |
| Example 2 | Compound 1a-2 | ◯ | 0.22 |
| Example 3 | Compound 1b-1 | ◯ | 0.23 |
| Example 4 | Compound 1b-2 | ◯ | 0.24 |
| Example 5 | Compound 1c-1 | ◯ | 0.19 |
| Example 6 | Compound 1c-2 | ◯ | 0.27 |
| Example 7 | Compound 1d-1 | ◯ | 0.24 |
| Example 8 | Compound 1d-2 | ◯ | 0.22 |
| Example 9 | Compound 1e-1 | ◯ | 0.27 |
| Example 10 | Compound 1e-2 | ◯ | 0.23 |
| Example 11 | Compound 1f-1 | ◯ | 0.27 |
| Example 12 | Compound 1f-2 | ◯ | 0.26 |
| Example 13 | Compound 1g | ◯ | 0.27 |
| Example 14 | Compound 1h | ◯ | 0.25 |
| Comparative Example 1 | Compound C1 | X | 0.73 |
| Comparative Example 2 | Compound C2 | X | 0.99 |

From the results of Table 1, it can be seen that the patterns formed by using the semiconductor photoresist compositions according to Examples 1 to 14 exhibited superior storage stability and coating uniformity compared to Comparative Examples 1 and 2.

Hereinbefore, embodiments of the present disclosure have been described and illustrated. It should, however, be apparent to a person having ordinary skill in the art that the present disclosure is not limited to the embodiments as described, and the subject matter of the present disclosure may be variously modified and transformed without departing from the spirit and scope of the present disclosure. Accordingly, the modified or transformed embodiments as such may not be understood separately from the technical ideas and aspects of the present disclosure, and the modified embodiments are within the scope of the claims of the present disclosure, and equivalents thereof.

Description of Symbols

100: substrate
102: thin film
104: resist underlayer
106: photoresist layer
106a: non-exposed region
106b: exposed region
108: photoresist pattern
112: organic layer pattern
110: patterned hardmask
114: thin film pattern

What is claimed is:

1. A semiconductor photoresist composition, comprising:
an organotin compound represented by Chemical Formula 1; and
a solvent:
ₘ(R¹)—Sn—(—S—L¹—X)ₙ Chemical Formula 1
wherein, in Chemical Formula 1,
L¹ is a single bond, or a substituted or unsubstituted C1 to C5 alkylene group,
R¹ is a substituted or unsubstituted C1 to C20 alkyl group, a substituted or unsubstituted C3 to C20 cycloalkyl group, a substituted or unsubstituted C2 to C20 alkenyl group, a substituted or unsubstituted C3 to C20 cycloalkenyl group, a substituted or unsubstituted C2 to C20 alkynyl group, a substituted or unsubstituted C3 to C20 cycloalkynyl group, a substituted or unsubstituted C6 to C30 aryl group, or a combination thereof,
m and n are each an integer, and 2≤m+n≤6,
X is OR², SR³, C(O)—L^{2—}OR⁴, or C(O)—L^{3—}SR⁵,
L² and L³ are each independently a single bond, or a substituted or unsubstituted C1 to C5 alkylene group,
R² and R³ are each independently a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and
R⁴ and R⁵ are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof.

2. The semiconductor photoresist composition of claim 1, wherein:
R² to R⁵ are each independently a substituted or unsubstituted C1 to C20 alkyl group, a substituted or unsubstituted C2 to C20 alkenyl group, a substituted or unsubstituted C2 to C20 alkynyl group, a substituted or unsubstituted C6 to C30 aryl group, or a combination thereof.

3. The semiconductor photoresist composition of claim 1, wherein:
R² to R⁵ are each independently a methyl group, an ethyl group, an n-propyl group, an n-butyl group, an n-pentyl group, an n-hexyl group, an n-heptyl group, an n-octyl group, an n-nonyl group, an n-decyl group, an iso-propyl group, an iso-butyl group, an iso-pentyl group, an iso-hexyl group, an iso-heptyl group, an iso-octyl group, an iso-nonyl group, an iso-decyl group, a sec-butyl group, a sec-pentyl group, a sec-hexyl group, a sec-heptyl group, a sec-octyl group, a tert-butyl group, a tert-pentyl group, a tert-hexyl group, a tert-heptyl group, a tert-octyl group, a tert-nonyl group, or a tert-decyl group.

4. The semiconductor photoresist composition of claim 1, wherein:
R¹ is a substituted or unsubstituted C3 to C20 branched alkyl group.

5. The semiconductor photoresist composition of claim 1, wherein:
R¹ is an iso-propyl group, an iso-butyl group, an iso-pentyl group, an iso-hexyl group, an iso-heptyl group, an iso-octyl group, an iso-nonyl group, an iso-decyl group, a sec-butyl group, a sec-pentyl group, a sec-hexyl group, a sec-heptyl group, a sec-octyl group, a tert-butyl group, a tert-pentyl group, a tert-hexyl group, a tert-heptyl group, a tert-octyl group, a tert-nonyl group, or a tert-decyl group.

6. The semiconductor photoresist composition of claim 1, wherein:
L¹ is a single bond, or a substituted or unsubstituted C1 to C3 alkylene group.

7. The semiconductor photoresist composition of claim 1, wherein:
4m-Fn6.

8. The semiconductor photoresist composition of claim 1, wherein:
m+n=4,
m is an integer of 0 to 2, and
n is an integer of 2 to 4.

9. The semiconductor photoresist composition of claim 1, wherein:
the organotin compound is one selected from the compounds of Group 1:

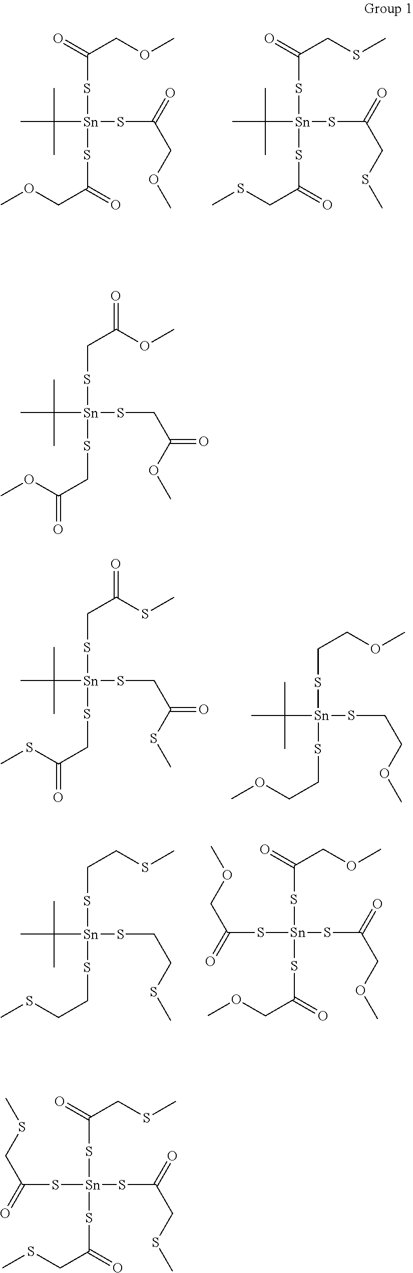

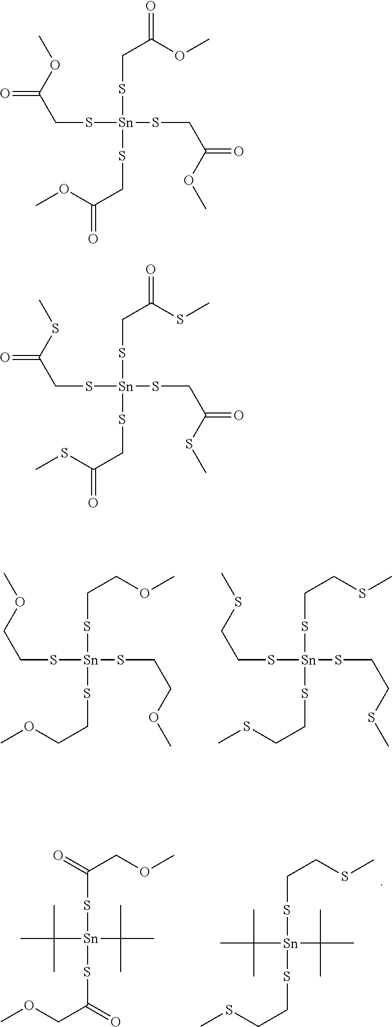

10. The semiconductor photoresist composition of claim 1, wherein:
the organotin compound is included in an amount of about 1 wt % to about 30 wt % based on 100 wt % of the semiconductor photoresist composition.

11. The semiconductor photoresist composition of claim 1, wherein:
the semiconductor photoresist composition further comprises an additive of a surfactant, a crosslinking agent, a leveling agent, or a combination thereof.

12. A method of forming patterns, comprising:
forming an etching-objective layer on a substrate;
coating the semiconductor photoresist composition of claim 1 on the etching-objective layer to form a photoresist layer;
patterning the photoresist layer to form a photoresist pattern; and
etching the etching-objective layer using the photoresist pattern as an etching mask.

13. The method of claim 12, wherein:
the photoresist pattern is formed using light having a wavelength of about 5 nm to about 150 nm.

14. The method of claim 12, wherein:
the method further comprises providing a resist underlayer formed between the substrate and the photoresist layer.

15. The method of claim 12, wherein:
the photoresist pattern has a width of about 5 nm to about 100 nm.
